(19) United States
(12) Patent Application Publication
(10) Pub. No.: US 2023/0286742 A1
(43) Pub. Date: Sep. 14, 2023

(54) WAFER STORAGE CONTAINER

(71) Applicants: Bum Je WOO, Gyeonggi-do (KR); PICO & TERA CO., LTD, Gyeonggi-do (KR)

(72) Inventor: Bum Je WOO, Gyeonggi-do (KR)

(73) Assignees: Bum Je WOO, Gyeonggi-do (KR); PICO & TERA CO., LTD, Gyeonggi-do (KR)

(21) Appl. No.: 18/013,548

(22) PCT Filed: Jun. 8, 2021
(86) PCT No.: PCT/KR2021/007148

§ 371 Date: Dec. 29, 2022

(30) Foreign Application Priority Data
Jul. 3, 2020 (KR) 10-2020-0082280

(51) Int. Cl. B65G 1/02; H01L 21/673

(52) U.S. Cl. CPC B65G 1/02; H01L 21/67389; B65G 2201/0297

(57) ABSTRACT

A wafer storage container according to an embodiment of the present invention comprises: a main body which includes an opening part at the front side thereof, and in which a wafer is accommodated; and an air current control part provided at one side of the main body, and the air current control part comprises a body the inside of which is empty; a compressed gas injection part provided at one side of the body and injecting a compressed gas into the body; and a compressed gas discharge part for discharging the compressed gas inside the body into the outside of the body, wherein the body extends by a predetermined length in a vertical or horizontal direction of the main body, and the main body includes a plurality of spray parts for spraying a purge gas into the inside thereof.

### TECHNICAL FIELD

The present disclosure relates to a wafer storage container and, more particularly, to a wafer storage container that blocks inflow of outside air and simultaneously discharges inside air.

### BACKGROUND ART

In general, a semiconductor device is manufactured by selectively and repeatedly performing a deposition process, a polishing process, a photolithography process, an etching process, an ion implantation process, a cleaning process, an inspection process, a heat treatment process, etc. on a wafer. For this purpose, the wafer is transferred to a specific location required in each process.

Wafers are high-precision products. These wafers are stored or transferred in a wafer storage container such as a front opening unified pod (FOUP) to prevent contamination or damage from external contaminants and shocks.

Process gases used in a semiconductor manufacturing process and fumes, which are by-products of the process, may remain on a wafer surface without being removed. This may cause contamination of semiconductor manufacturing equipment or a defective etching pattern of the wafer during the process, resulting in a decrease in reliability of the wafer.

In an attempt to solve the above problem, purging technologies have recently been developed to remove fumes remaining on the surface of a wafer or prevent oxidation of the wafer by supplying a purge gas to the wafer stored in a wafer storage container.

In order to achieve purging of the wafer stored in the wafer storage container, the wafer storage container is combined with a supply device capable of supplying a purge gas, such as a load port, and supplies the purge gas to the wafer stored in the wafer storage container. Thus, the wafer storage container is provided with a passage for flow of the purge gas supplied from the supply device and a spray hole for injection of the purge gas.

A contaminated purge gas resulting from combination with fumes inside the wafer storage container may be discharged to the outside of the wafer storage container. At this time, an air current controller for controlling the air current of the purge gas may be provided on one side or outside of the wafer storage container.

An example of a wafer storage container having an air current controller on an outside thereof is disclosed in Korean Patent No. 10-1444241 (hereinafter, referred to as “Patent Document 1”).

In Patent Document 1, an exhaust device is provided on one side of a cleaning device for accommodating wafers. The exhaust device may be provided at a position lower than a wafer accommodating space so that the flow direction of a purge gas discharged from the wafer accommodating space is oriented downwards. While the cleaning device can smoothly discharge the purge gas to a lower side thereof through the exhaust device, it has a limitation in that outside air is introduced into an upper side of the cleaning device due to such a downward flow of the purge gas.

An example of a wafer storage container having an air current controller on one side thereof is disclosed in Korean Patent No. 10-1090350 (hereinafter, referred to as “Patent Document 2”).

In Patent Document 2, a fume removal device is provided for loading wafers therein, and includes an air curtain on an open side thereof. In this case, an air curtain can wash the wafers entering the fume removal device and at the same time, prevent a reverse flow of fumes. However, since the function of such an air curtain is limited to preventing outside air from entering the fume removal device, it does not provide any function of discharging contaminated gas inside the fume removal device to the outside.

### DOCUMENTS OF RELATED ART

### Patent Documents

(Patent Document 1) Korean Patent No. 10-1444241
(Patent Document 2) Korean Patent No. 10-1090350

### DISCLOSURE OF INVENTION

### Technical Problem

Accordingly, the present disclosure has been made keeping in mind the above problems occurring in the related art, and an objective of the present disclosure is to provide a wafer storage container that blocks inflow of outside air and simultaneously discharges inside air.

Another objective of the present disclosure is to provide a wafer storage container that prevents occurrence of a dead area of inside air.

### Solution to Problem

According to one aspect of the present disclosure, there is provided a wafer storage container including: a housing including an opening on a front side thereof and configured to accommodate a wafer therein; and an air current controller provided on one side of the housing, wherein the air current controller may include: a body provided in a hollow shape; a compressed gas injection hole provided on one side of the body and configured to inject a compressed gas into the body; and a compressed gas discharge guide configured to discharge the compressed gas inside the body to an outside of the body, the body may be provided in a shape extending a predetermined length in a vertical or horizontal direction of the housing, and the housing may include a plurality of spray slots configured to spray a purge gas to an inside of the housing.

Furthermore, the air current controller may be detachably coupled to the housing.

Furthermore, the air current controller may be detachably coupled to a wafer transfer automation module (equipment front end module (EFEM)) provided separately from the housing.

Furthermore, the air current controller may be provided on each of left and right sides of the opening.

Furthermore, the air current controller may be further provided on each of upper and lower sides of the opening, and the body of the air current controller provided on each of the upper, lower, left, and right sides of the opening may have a communication space therein.

Furthermore, the space inside the body may serve as a space in which the compressed gas flows.

Furthermore, the compressed gas discharge guide may be provided in a shape having a portion that is curved toward the space.

Furthermore, the compressed gas inside the space may be discharged along the compressed gas discharge guide, and the compressed gas may be discharged to an outside of the housing through the opening together with the purge gas inside the housing.

Furthermore, the housing may include: a first housing having open front and rear sides; and a second housing having an open front side, and the air current controller may be provided between the first housing and the second housing.

Furthermore, the compressed gas discharge guide may be provided at a position closer to the second housing than the first housing.

Furthermore, the air current controller may be provided in a shape conforming to the first housing and the second housing, the body may have a communication space therein, and the space inside the body may serve as a space in which the compressed gas flows.

Furthermore, the compressed gas discharge guide may be provided in a shape curved toward the space, the compressed gas inside the space may be discharged along the compressed gas discharge guide, and the compressed gas may be discharged to an outside of the housing through the opening together with the purge gas inside the housing.

According to another aspect of the present disclosure, there is provided a wafer storage container including: a housing including an opening on a front side thereof and configured to receive a purge gas therein; and an air current controller provided on one side of the housing and configured to supply a compressed gas into the housing, wherein the airflow controller may include: a compressed gas discharge guide configured to discharge the compressed gas into the housing; and a body provided in a hollow shape and having a side on which a compressed gas discharge guide is formed, wherein when the compressed gas is discharged forward from rear of the housing along the compressed gas discharge guide, a pressure in front of the air current controller may become higher than a pressure behind the air current controller and thereby an air current flowing forward from rear of the housing may be generated.

Furthermore, the air current controller may be detachably coupled to the one side of the housing at a position closer to front than to rear of the housing.

Furthermore, the air current controller may be detachably coupled to the opening of the housing.

Furthermore, the air current controller may be provided on the opening of the housing through an installation member at a predetermined interval from the housing.

Furthermore, the air current controller may be directly coupled to the housing through the installation member or may be installed on a ground or ceiling at an installation location.

Furthermore, a blocking partition may be provided inside the housing, and the inside of the housing may be divided into a plurality of areas by the blocking partition.

Furthermore, the air current controller may be provided in each of the plurality of areas.

Furthermore, the wafer storage container may further include a door, wherein the door may be configured to selectively open and close a front side of each of the plurality of areas.

According to another aspect of the present disclosure, there is provided a wafer storage container including: a housing configured to accommodate a wafer therein; and an air current controller provided on one side of the housing, wherein a plurality of wafers may be loaded at a predetermined interval in the housing, a purge gas may be charged into the housing, and the air current controller may include: a body provided in a hollow shape; and a compressed gas discharge guide formed in a shape curved toward an inside of the body in a rear-to-front direction of the housing, wherein a compressed gas inside the body may be discharged forward from rear of the housing along the compressed gas discharge guide, and a flow of air inside the body may be formed in a horizontal direction of the wafers.

### Advantageous Effects of Invention

As described above, a wafer storage container according to the present disclosure can simultaneously achieve blocking of inflow of outside air and discharge of inside air.

Furthermore, it is possible to prevent occurrence of a dead area of inside air.

### BRIEF DESCRIPTION OF DRAWINGS

FIG. 1 is a perspective view illustrating a wafer storage container according to a first embodiment of the present disclosure.

FIG. 2 is a sectional view taken along line A-A′ of FIG. 1.

FIG. 3 is a sectional view taken along line B-B′ of FIG. 1.

FIG. 4 is a perspective view illustrating the wafer storage container illustrated in FIG. 1, which includes a door.

FIG. 5 is a perspective view illustrating a wafer storage container according to a second embodiment of the present disclosure.

FIG. 6 is a sectional view taken along line C-C′ of FIG. 5.

FIG. 7 is a perspective view illustrating a wafer storage container according to a third embodiment of the present disclosure.

FIG. 8 is a perspective view illustrating a wafer storage container according to a fourth embodiment of the present disclosure.

FIG. 9 is a sectional view taken along line D-D′ of FIG. 8.

FIG. 10 is a perspective view illustrating a modified example of the fourth embodiment.

### MODE FOR THE INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that this present disclosure is not limited to the embodiments and the conditions.

The above described objectives, features, and advantages will be more apparent through the following detailed description related to the accompanying drawings, and thus those of ordinary skill in the art may easily implement the technical spirit of the present disclosure.

Hereinafter, a first embodiment of the present disclosure will be described in detail with reference to the accompanying drawings.

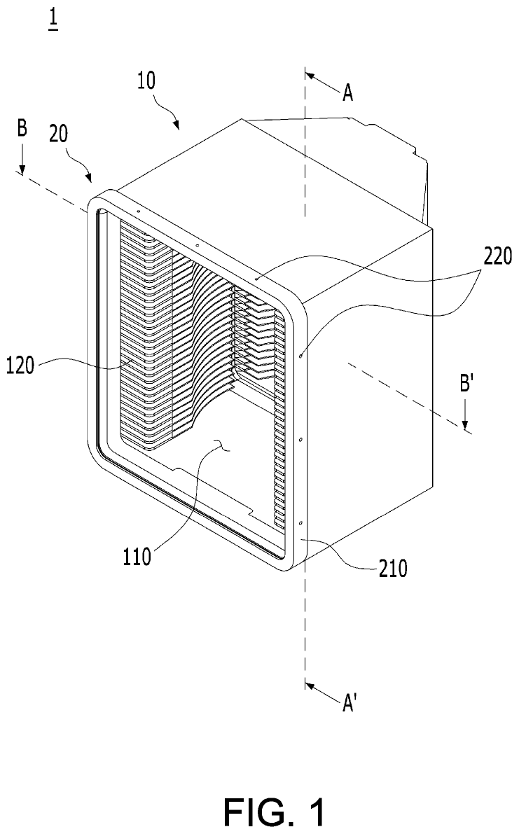

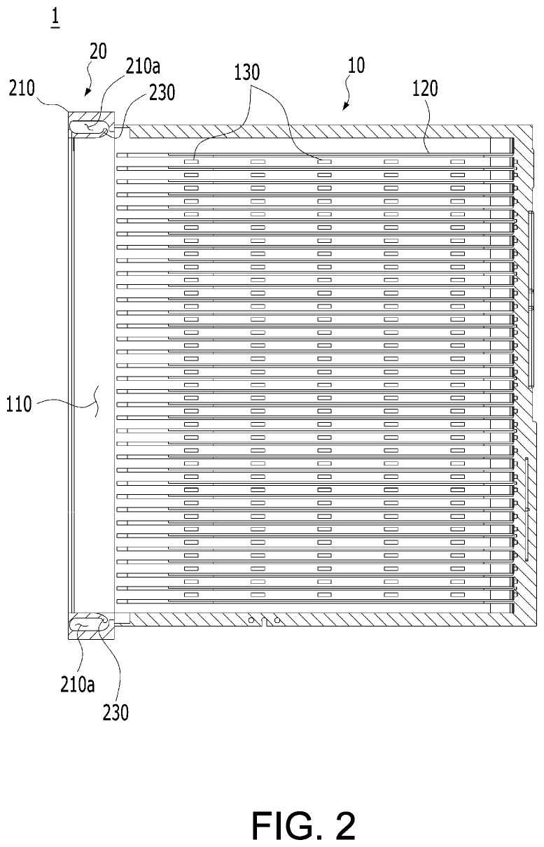

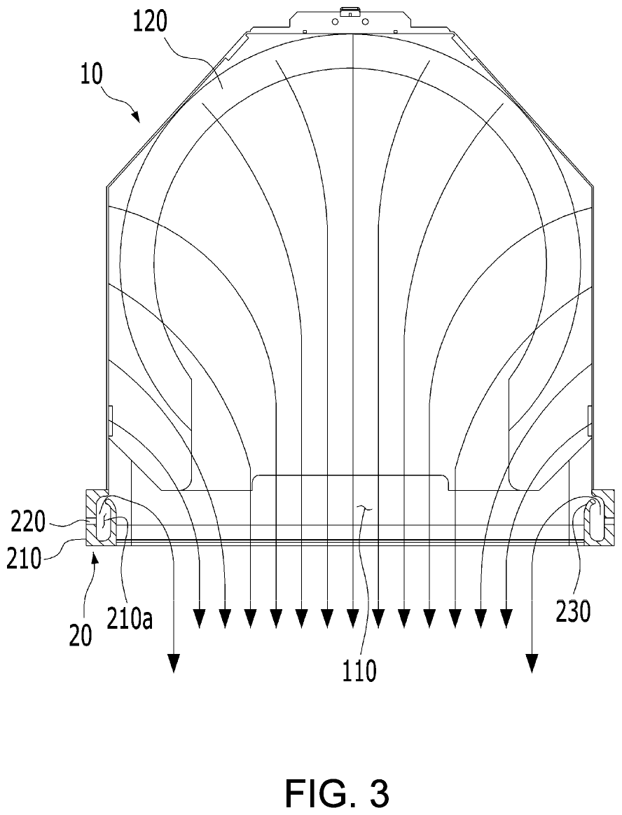

FIG. 1 is a perspective view illustrating a wafer storage container according to a first embodiment of the present disclosure. FIG. 2 is a sectional view taken along line A-A′ of FIG. 1. FIG. 3 is a sectional view taken along line B-B′ of FIG. 1.

Referring to FIGS. 1 to 3, the wafer storage container 1 according to the first embodiment of the present disclosure may include a housing 10 in which a wafer is accommodated, and an air current controller 20 provided on one side of the housing 10.

The housing 10 provides a space in which a plurality of wafers are accommodated, and may include an opening 110 formed on a front side thereof, a shelf 120 on which a wafer is loaded, and a spray slot 130 for spraying a purge gas. Here, the term “purge gas” is a general term for an inert gas for removing fumes, and in particular, may be nitrogen (N2) gas, which is one of inert gases.

The opening 110 is provided on the front side of the housing 10, and may be a passage for loading or unloading of the wafers into or out of the housing 10. Specifically, the opening 110 may be provided to have a quadrangular cross-section, and the length of one side of the opening 110 may be greater than the diameter of each of the wafers. Although it has been exemplarily described in this embodiment that the opening 110 has a quadrangular cross-section, the shape of the opening 110 is not limited thereto. For example, the opening 110 may have a circular cross-section.

A plurality of shelves 120 may be provided inside the housing 10. The shelf 120 is for supporting the wafer. The plurality of shelves 120 may be provided in a horizontal direction of the housing 10. Specifically, the shelves 120 may be fixed to an inner wall of the housing 10 at a predetermined interval. Thus, the wafer may be provided between each pair of the shelves 120. In other words, the plurality of wafers may be loaded inside the housing 10 at a predetermined interval.

The housing 10 may include a plurality of spray slots 130. The plurality of spray slots 130 may be provided on the inner wall of the housing 10. The spray slots 130 are for spraying the purge gas into the housing 10. Specifically, a supply part (not illustrated) for supplying the purge gas may be provided on one side of the housing 10. The purge gas supplied through the supply part may be sprayed through the spray slots 130. The spray slots 130 may be provided at positions that do not overlap with the shelves 120. For example, an array of a plurality of spray slots 130 may be provided between each pair of the shelves 120. In other words, the spray slots 130 may be provided on opposite side surfaces and a rear surface of the inner wall of the housing 10. Thus, after the wafers are loaded on the shelves 120, the purge gas sprayed through the spray slots 130 may be easily provided to upper surfaces of the wafers. In other words, fumes on the upper surfaces of the wafers may be removed through the purge gas.

Regardless of whether the purge gas is sprayed through the spray slots 130, the purge gas may be charged into the housing 10. Specifically, after the purge gas is charged into the housing 10, the spray slots 130 may be operated. In addition, upon the operation of the spray slots 130, the purge gas previously charged may be discharged to the outside of the housing 10 and a new purge gas may be supplied through the spray slots 130. Thus, the purge gas inside the housing 10 may be continuously circulated.

Although it has been exemplarily described in this embodiment that the spray slots 130 are provided on the inner wall of the housing 10, the position of the spray slots 130 is not limited thereto. For example, the spray slots 130 may be provided in the shelves 120. In this case, the supply part may also be provided in the shelves 120, and accordingly, the inside of each of the shelves 120 may serve as a space in which the purge gas flows.

The air current controller 20 may be provided on one side of the housing 10. The air current controller 20 is for controlling the air current of a compressed gas inside the housing 10, and may include a body 210 provided in a hollow shape, a compressed gas injection hole 220 for injecting the compressed gas into the body 210, and a compressed gas discharge guide 230 for discharging the compressed gas to the outside of the body 210. Here, the compressed gas means an inert gas, and may be the same or different gas from the purge gas.

Specifically, the air current controller 20 may be detachably coupled to the opening 110 of the housing 10, and may be provided on each of upper, lower, left and right sides of the opening 110. At this time, the body 210 of the air current controllers 20 provided on each of the upper, lower, left, and right sides of the opening 110 may be provided to have a communication space therein. Although it has been exemplarily described in this embodiment that the air current controller 20 is provided on each of the upper, lower, left, and right sides of the opening 110, the shape of the air current controller 20 is not limited thereto. For example, the air current controller 20 may be provided only on each of the left and right sides of the opening 110. In addition, the position of the air current controller 20 is not limited to being coupled to the housing 10. For example, the air current controller 20 may be detachably coupled to a separate wafer transfer automation module (equipment front end module (EFEM)).

The bodies 210 may be provided in a shape extending a predetermined length in a vertical direction or a horizontal direction of the housing 10. Specifically, a part of the bodies 210 provided on the left and right sides of the opening 110 may extend in the vertical direction of the housing 10, and a part of the bodies 210 provided on the upper and lower sides of the opening 110 may extend in the horizontal direction of the housing 10.

The body 210 may include a space 210a therein, and may be provided with the compressed gas injection hole 220 on a first side thereof and the compressed gas discharge guide 230 on a second side thereof. Specifically, a plurality of compressed gas injection holes 220 may be formed on an outer side of the body 210, and the compressed gas discharge guide 230 may be formed on an inner side of the body 210. Here, the outer side of the body 210 means a side corresponding to the outside of the housing 10, and the inner side thereof means a side corresponding to the inside of the housing 10.

The compressed gas injection holes 220 may supply the compressed gas supplied through an external supply source (not illustrated) into the body 210. The compressed gas supplied to the body 210 through the compressed gas injection holes 220 may flow in the space 210a. In other words, the space 210a inside the body 210 may serve as a space in which the compressed gas flows.

The body 210 may be formed in a shape having an opening on the inner side thereof. At this time, the inner side of the body 210 having the opening may define the compressed gas discharge guide 230.

The compressed gas discharge guide 230 may be formed in a shape having a portion that is curved toward the space 210a. Specifically, the compressed gas discharge guide 230 may be provided on the inner side of the body 210, and may have a shape curved toward the space 210a of the body 210 in a front-to-rear direction. Thus, the compressed gas inside the space 210a may be discharged to the outside of the body 210 along the shape of the compressed gas discharge guide 230 and then moved forward from the rear of the housing 10. At this time, the compressed gas discharged to the outside of the body 210 may be discharged through the opening 110 of the housing 10 together with the purge gas inside the housing 10 (see the arrow in FIG. 3). In other words, the purge gas from which fumes of the wafers are removed inside the housing 10 may be discharged to the outside of the housing 10 through the compressed gas discharged through the air current controller 20 without requiring the use of a separate power.

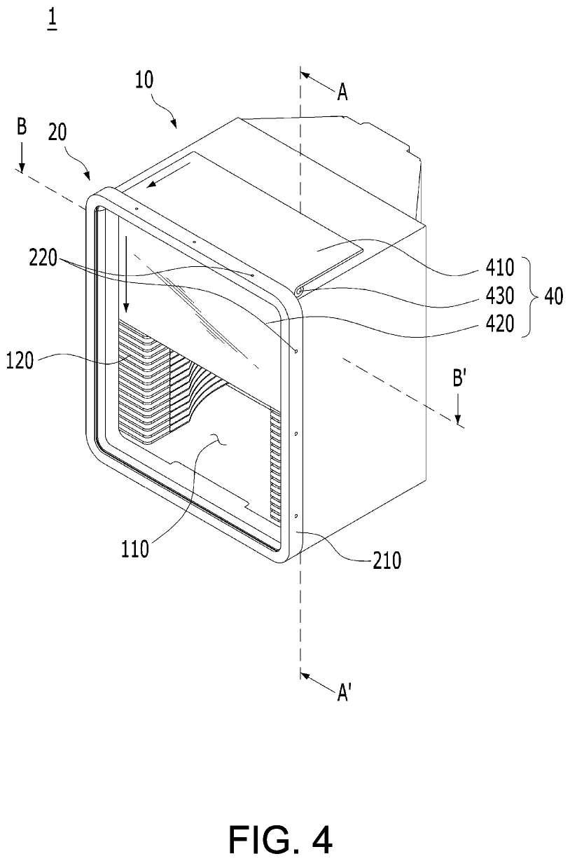

FIG. 4 is a perspective view illustrating the wafer storage container illustrated in FIG. 1, which includes a door.

Referring to FIG. 4, the housing 10 may be provided with a door 40. The door 40 may be provided on one side of the housing 10, and may seal an inner area of the housing 10.

The door 40 may be provided on the housing 10 so as to be selectively opened and closed. Specifically, the door 40 may be opened when it is necessary to discharge air inside the housing 10, and the door 40 may be closed when it is necessary to charge the purge gas into the housing 10. In other words, the purge gas inside the housing 10 may be discharged by opening the door 40.

The door 40 may be provided on the opening 110 of the housing 10, and may be separately provided outside the housing 10. In addition, as a means for opening and closing the door 40 is not limited as long as it is configured to open or close the opening 110 of the housing 10.

In this embodiment, a case in which the door 40 is operated through a roller to open and close the inner area of the housing 10 will be described as an example.

The door 40 may include a first door 410, a second door 420, and an actuator 430. At this time, the first door 410 and the second door 420 may be integrally formed, and the actuator 430 may be provided between the first door 410 and the second door 420.

The first door 410 may be provided on one side of the housing 10, and the actuator 430 may be provided on one side of the air current controller 20. In addition, the second door 420 may be provided on one side of the housing 10 or on the opening 110 of the housing 10 depending on whether the housing 10 is opened or closed.

The actuator 430 is for controlling the first door 410 and the second door 420, and may be provided as a roller. The first door 410 and the second door 420 may be made of a deformable material, and may be provided in a shape wound on the actuator 430.

Specifically, the first door 410 and the actuator 430 may be provided on an upper side of the housing 10, and the actuator 430 may move the first door 410 and the second door 420 downward from the upper side of the opening 110. Although it has been exemplarily described in this embodiment that the first door 410 and the actuator 430 are provided on the upper side of the housing 10, the positions of the first door 410 and the actuator 430 are not limited thereto. For example, the first door 410 and the actuator 430 may be provided on a left or right side of the housing so that the first door 410 and the second door 420 are moved to the right or left, and alternatively, the first door 410 and the actuator 430 may be provided on a lower side of the housing 10 so that the first door 410 and the second door 420 are moved upward from the lower side of the opening 110.

When the door 40 needs to be opened to discharge air inside the housing 10, the actuator 430 may wind one side of the first door 410 and the second door 420. When the door needs to be closed to charge the purge gas into the housing 10, the actuator 430 may unwind and move the second door 420 toward the lower side of the opening 110. In other words, the second door 420 wound on the actuator 430 may be moved toward the opening 110 to cover the opening 110. At this time, the first door 410 may be moved toward the front of the housing 10 in conjunction with the movement of the second door 420.

When the closed door 40 needs to be opened again, the actuator 430 may wind and move the second door 420 closing the opening 110 toward the upper side of the opening 110 again. At this time, the first door 410 may be moved toward the rear of the housing 10 in conjunction with the movement of the second door 420. Thus, the housing 10 may be selectively opened or closed through the door 40.

Hereinafter, the operation and effects of the wafer storage container 1 according to the first embodiment of the present disclosure having the above configuration will be described.

First, the purge gas may be sprayed into the housing 10 through the spray slots 130. At this time, the spray slots 130 may be operated regardless of whether the wafers are provided inside the housing 10. Thus, the spray slots 130 may be operated even at the moment when the wafers are loaded and unloaded through the opening 110.

When the purge gas is sprayed through the spray slots 130, fumes on the wafers inside the housing 10 may be removed. At this time, since the array of the plurality of spray slots 130 may be provided between each pair of the shelves 120 and may be provided on the opposite side surfaces and the rear surface of the inner wall of the housing 10, the purge gas may be uniformly sprayed to the wafers loaded inside the housing 10.

The air current controller 20 may be provided on the opening 110. The air current controller 20 may be provided in a hollow shape, and may receive the compressed gas from the external supply source. Thus, the inside of the air current controller 20 may serve as a space in which the compressed gas flows.

The compressed gas supplied into the body 210 through the compressed gas injection holes 220 may be discharged to the outside of the body 210 along the compressed gas discharge guide 230. The compressed gas discharge guide 230 may be formed in a shape curved toward the inside of the body 210 in the front-to-rear direction. Thus, the compressed gas may be moved along the shape of the compressed gas discharge guide 230 and then moved forward from the rear of the body 210.

When the compressed gas is discharged forward from the rear of the housing 10 along the compressed gas discharge guide 230, the pressure inside the housing 10 which is an area behind the air current controller 20 may become higher than that of an area in front of the air current controller 20. As a result, as an air current flowing forward from the rear of the housing 10 is generated, and the purge gas inside the housing 10 may be discharged to the outside. At this time, the flow of the purge gas inside the housing 10 may be formed in a horizontal direction of the wafers. In other words, the direction of the air current inside the housing 10 may be changed through the shape of the compressed gas discharge guide 230 without requiring the use of a separate power.

In addition, as the flow of the compressed gas and the purge gas is guided forward from the rear of the housing 10, outside air may be blocked from flowing into the housing 10 and simultaneously inside air may be discharged.

Meanwhile, when the spray slots 120 are provided on the opposite side surfaces and the rear surface of the inner wall of the housing 10, the purge gas may not be supplied to a side of the wafer corresponding to the front of the housing 10. At this time, as the purge gas is discharged to the outside of the housing 10 through the air current controller 20, the purge gas may be easily supplied to the front of the wafer. In other words, it is possible to prevent occurrence of a dead area of inside air.

In addition, as the door 40 is provided on one side of the housing 10, charge and discharge of the purge gas with respect to the housing 10 may be selectively performed depending on whether the door 40 is opened or closed.

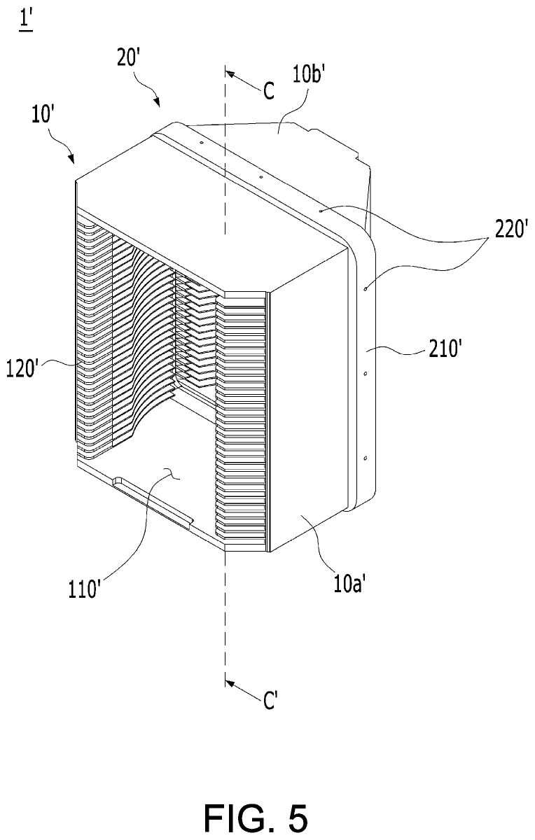

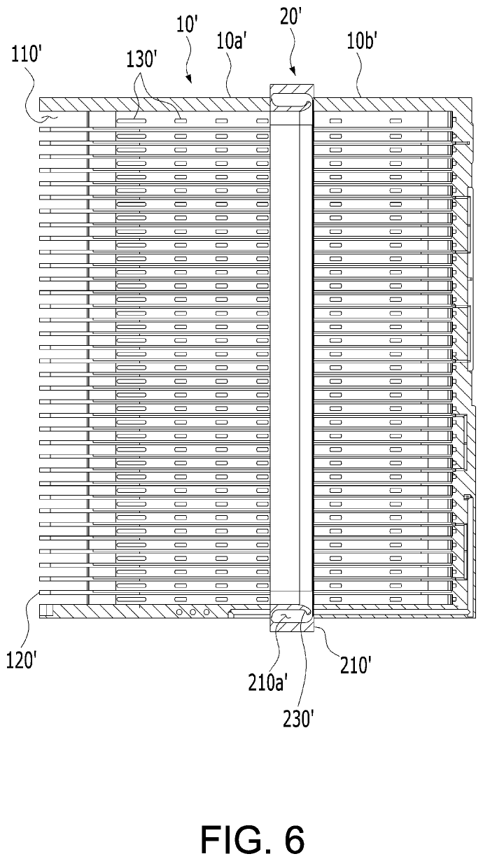

Hereinafter, a wafer storage container according to a second embodiment of the present disclosure will be described with reference to FIGS. 5 and 6. However, since the second embodiment is different from the first embodiment in the position of an air current controller 20′ and the shape of a housing 10′, this difference will be mainly described, and the description and reference numerals of the first embodiment are used for the same parts.

FIG. 5 is a perspective view illustrating the wafer storage container according to the second embodiment of the present disclosure. FIG. 6 is a sectional view taken along line C-C′ of FIG. 5.

Referring to FIGS. 5 and 6, the wafer storage container 1′ according to the second embodiment of the present disclosure may include a first housing 10a′ having open front and rear sides, and a second housing 10b′ having an open front side. Specifically, the first housing 10a′ and the second housing 10b7 may be provided in corresponding sizes, and may be provided at a predetermined interval. In this case, the air current controller 20′ may be provided between the first housing 10a′ and the second housing 10b′.

The air current controller 20′ may be detachably coupled to the first housing 10a′ and the second housing 10b′. Specifically, the air current controller 20′ may be provided between the first housing 10a′ and the second housing 10b′, and an opening 110′ may be provided on the front side of the first housing 10a′.

A compressed gas discharge guide 230′ of the air current controller 20′ may be provided at a position closer to the second housing 10b′ than to the first housing 10a′. Specifically, the compressed gas discharge guide 230′ may be formed in a shape curved toward a space 210a′ inside the housing 210′ in a direction from the first housing 10a′ to the second housing 101D′. Thus, a compressed gas flowing in the space 210a′ may be moved from the second housing 10b′ toward the first housing 10a′ and then discharged through the opening 110′.

When the compressed gas is discharged along the compressed gas discharge guide 230′, as the pressure of the second housing 10b′ which is an area behind the air current controller 20′ may become higher than that of the first housing 10a′ which is an area in front of the air current controller 20′, an air current flowing from the second housing 10b′ to the first housing 10a′ may be generated. At this time, a purge gas charged in the housing 10′ or a purge gas supplied through a plurality of spray slots 130′ may meet the compressed gas supplied from the air current controller 20′ inside the housing 10′, thereby forming the same flow as the flow of the compressed gas. In other words, the purge gas inside the housing 10′ may be discharged to the outside of the housing 10′ through the opening 110′.

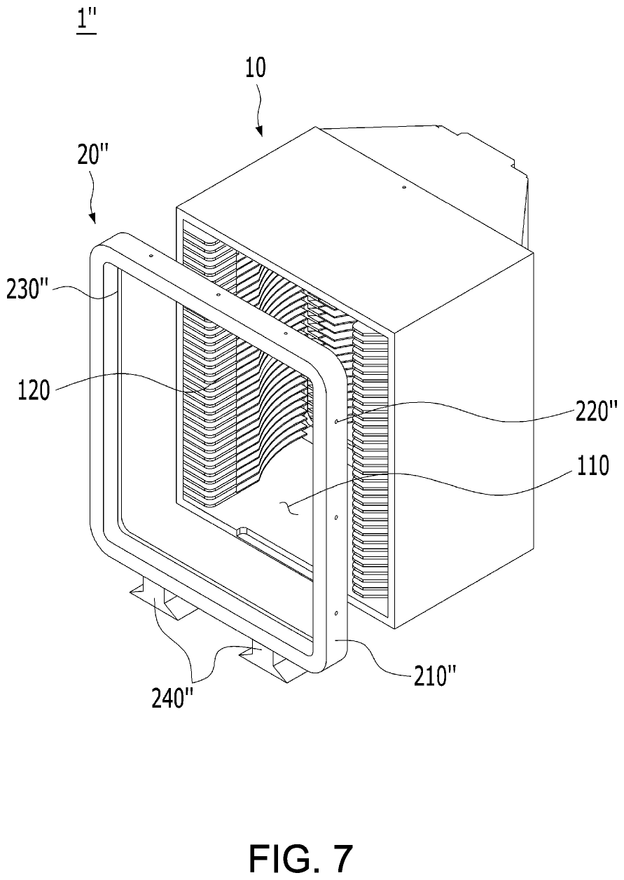

Hereinafter, a wafer storage container according to a third embodiment of the present disclosure will be described with reference to FIG. 7. However, since the third embodiment is different from the first embodiment in the coupling manner between an air current controller 20′ and a housing 10′, this difference will be mainly described, and the description and reference numerals of the first embodiment are used for the same parts.

FIG. 7 is a perspective view illustrating the wafer storage container according to the third embodiment of the present disclosure.

Referring to FIG. 7, the wafer storage container 1″ according to the third embodiment of the present disclosure may include the air current controller 20″ provided at a predetermined interval from the housing 10. Specifically, the air current controller 20″ may be provided at a predetermined position through an installation member 240″. In this case, the installation member 240″ may be provided as a bracket.

The air current controller 20″ may be provided on an opening 110 of the housing 10. A purge gas inside the housing 10 may be discharged to the outside of the housing through the air current controller 20″. Specifically, as an air current flowing forward from the rear of the housing is generated through the air current controller 20″, the purge gas inside the housing 10 may be discharged forward to the front of the air current controller 20″. At this time, outside air may be introduced through a gap between the air current controller 20″ and the housing 10. In other words, not only the purge gas inside the housing 10 but also the inflow air between the air current controller 20″ and the housing 10 may be provided to the rear of the air current controller 20″, and accordingly, such a rear-to-front air current flowing forward from the rear of the air current controller 20″ may be generated more easily. Thus, the purge gas inside the housing 10 may also be easily discharged forward from the rear of the housing 10.

In addition, as the inflow gas between the air current controller 20″ and the housing 10 is provided to the rear of the air current controller 20″ to thereby facilitates the generation of the rear-to-front air current, a reverse flow phenomenon in which air is introduced from the outside to the inside of the housing 10 may be prevented.

Although it has been exemplarily described in this embodiment that the installation member 240″ is provided as a bracket and two brackets are provided on the bottom of the air current controller 20″ to be installed on the ground, the installation method of the air current controller 20″ is not limited thereto. For example, the air current controller 20″ may be directly coupled to the housing 10 through a bracket, or may be installed in a form suspended from the ceiling at an installation location through the installation member 240″.

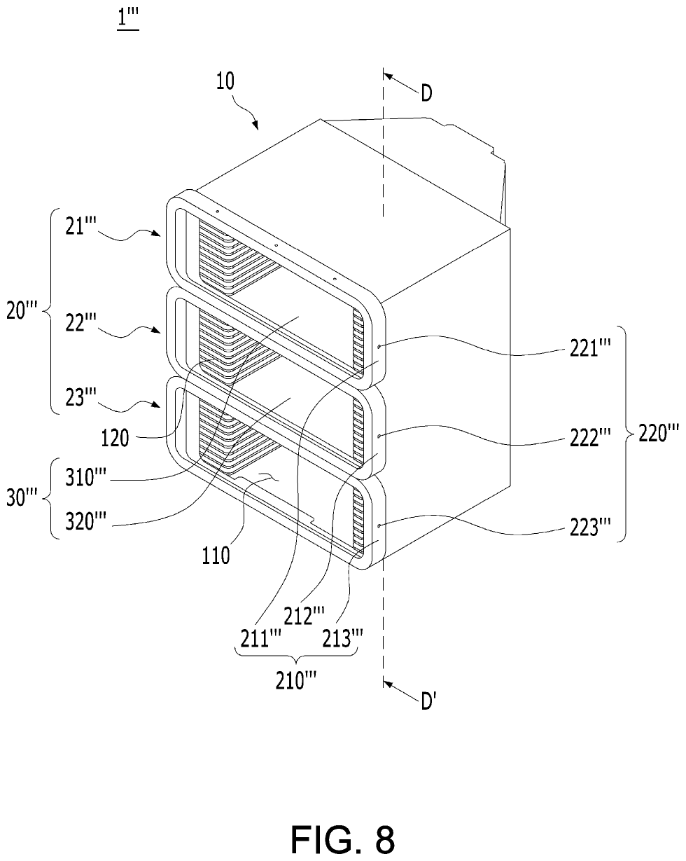

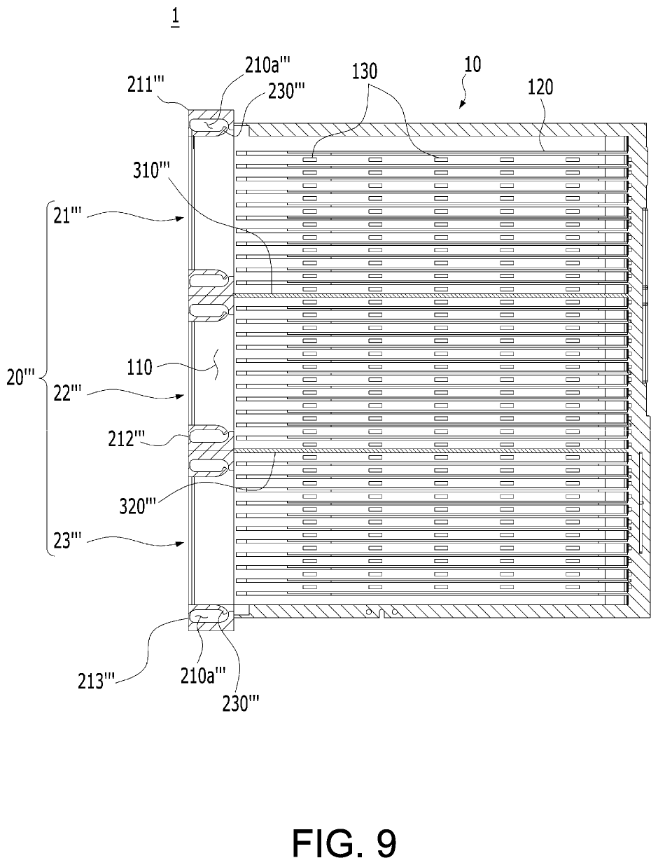

Hereinafter, a wafer storage container according to a fourth embodiment of the present disclosure will be described with reference to FIGS. 8 and 9. However, since the fourth embodiment is different from the first embodiment in that a plurality of air current controllers 20″ are provided, this difference will be mainly described, and the description and reference numerals of the first embodiment are used for the same parts.

FIG. 8 is a perspective view illustrating the wafer storage container according to the fourth embodiment of the present disclosure. FIG. 9 is a sectional view taken along line D-D′ of FIG. 8.

Referring to FIGS. 8 and 9, the wafer storage container 1′″ according to the fourth embodiment of the present disclosure may include the plurality of air current controllers 20′″ provided on one housing 10, and a blocking partition 30′″ conforming to the size of the housing 10 may be provided inside the housing 10.

The blocking partition 30′″ is for dividing the inside of the housing 10, and may be provided on one side of the loading portion 120. Specifically, a plurality of blocking partitions 30′″ may be provided in a horizontal direction of the housing 10, and may be provided to be in contact with all surfaces of an inner wall of the housing 10. Thus, when the blocking partitions 30′″ are provided inside the housing 10, the inside of the housing 10 may be divided into upper and lower portions by the blocking partitions 30′″.

When two blocking partitions 30′″ are provided in one housing 10, the blocking partitions 30′″ may include a first blocking partition 310′″ and a second blocking partition 320′″ provided below the first blocking partition 310′″ at a predetermined interval therefrom. Thus, the inside of the housing 10 may be divided into a first area above the first blocking partition 310′″, a second area between the first blocking partition 310′″ and the second blocking partition 320′″, and a third area below the second blocking partition 320′″. In this case, the first blocking partition 310′″ and the second blocking partition 320′″ may be positioned so that the first area, the second area, and the third area have the same width. Although it has been exemplarily described in this embodiment that the two blocking partitions 30′″ are provided in the housing 10 and the inside of the housing 10 is divided into three areas, the number of the blocking partitions 30′″ is not limited thereto. For example, three blocking partitions 30′″ may be provided in the housing 10 and the inside of the housing 10 may be divided into four areas.

An air current controller 20′″ may be provided in each area of the housing 10. The air current controller 20′″ may be provided to correspond to each area of the housing 10 partitioned by the blocking partitions 30′″. For example, when the two blocking partitions 30′″ are provided and the inside of the housing 10 is divided into three areas, three air current controllers 20′″ may be provided.

In the housing 10, the first to third areas may be provided through the two blocking partitions 30′″. The first area may be provided at the uppermost side, the third area may be provided at the lowermost side, and the second area may be provided between the first area and the third area. In addition, a first air current controller 21′″ may be provided in an opening 110 of the first area, a second air current controller 22′″ may be provided in an opening 110 of the second area, and a third air current controller 23′″ may be provided in an opening 110 of the third area. In this case, respective bodies 211′″, 212′″, and 213′″ of the first air current controller 21′″, the second air current controller 22′″, and the third air current controller 33′″ may all be formed in the same shape and size, and compressed gas injection holes 221′″, 222′″, and 223′″ may be provided at the same corresponding positions the respective bodies 211′″, 212′″, and 213′″.

A compressed gas supplied into the bodies 211′″, 212′″, and 213′″ through the compressed gas injection holes 221′″, 222′″, and 223′″ may be discharged to the outside of the bodies 211′″, 212′″, and 213′″ along respective compressed gas discharge guides 230′″. At this time, as the plurality of air current controllers 20′″ are provided in one housing and the compressed gas is supplied and discharged through each of the air current controllers 21′″, 22′″, and 23′″, more efficient supply and discharge of the compressed gas may be achieved than when one air current controller is provided. In other words, air inside the housing 10 may be efficiently discharged to the outside of the housing 10 through the air current controllers 21′″, 22′″, and 23′″.

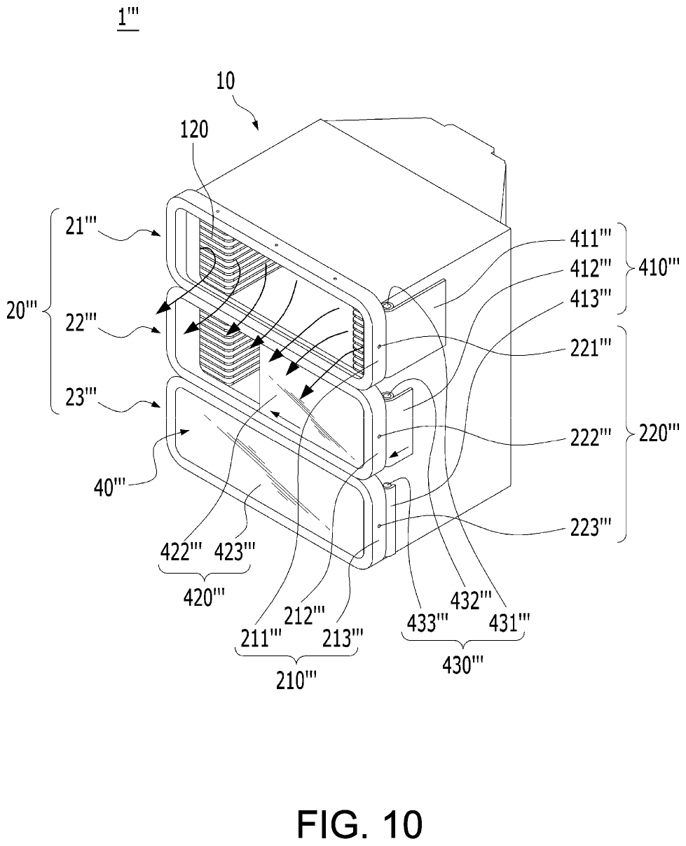

FIG. 10 is a perspective view illustrating a modified example of the fourth embodiment.

Referring to FIG. 10, a housing 10 may be provided with a door 40′″. The door 40′″ may be provided on one side of the housing 10, and may seal each inner area of the housing 10 partitioned by air current controllers 21′″, 22′″, and 23′″.

The door 40′″ may be provided on each of the air current controllers 21′″, 22′″, and 23′″ so as to be selectively opened and closed. Specifically, the door 40′″ may be opened when it is necessary to discharge air inside the housing 10, and the door 40′″ may be closed when it is necessary to charge the purge gas into the housing 10.

The door 40′″ may be provided on an opening of each of the first to third air current controllers 21′″, 22′″, and 23′″, or may be separately provided outside the housing 10. In addition, as a means for opening and closing the door 40′″ is not limited as long as it is configured to open or close an opening of the housing 10.

First doors 411′″, 412′″, and 413′″ and actuators 431′″, 432′″, and 433′″ may be provided on a right side of the housing 10. The actuators 431′″, 432′″, and 433′″ may move the first doors 411′″, 412′″, and 413′″ and the second doors 421′″, 422′″, and 423′″ to the left from the right side of the housing 10.

When the door 40′″ needs to be opened to discharge air inside the housing 10, the actuator 431′″ may wind one side of the first door 411′″ and the second door 421′″ as illustrated in a first area. When the door 40′″ needs to be closed to charge a purge gas into the housing 10, the actuator 432′″ may unwind and move the second door 422′″ to the left from the right side of the housing 10 as illustrated in a second area. In other words, the second door 422′″ wound on the actuator 432′″ may be moved toward the opening of the housing 10. When the operation of the actuator 433′″ is completed, the second door 422′″ may be positioned at positions covering the entire opening of the housing 10 as illustrated in a third area. Thus, the housing 10 may be selectively opened or closed through the door 40′″. In other words, depending on whether the door 40′″ is provided, charge and discharge of the purge gas with respect to the housing 10 may be simultaneously performed.

Although the wafer storage container according to the present disclosure has been described with reference to a specific embodiment thereof, the description is illustrative of the present disclosure and is not to be construed as limiting the present disclosure. Various modifications, additions, and substitutions may occur to those skilled in the art without departing from the spirit and scope of the present disclosure as defined by the appended claims.

[Description of the Reference Numerals in the Drawings]
1, 1′, 1″, 1′″: wafer storage container
10, 10′: housing 110, 110′: opening
120, 120′: shelve 130, 130′: spray slot
20, 20′, 20″, 20′″: air current controller
210, 210′, 210″, 210′″: body
220, 220′, 220″, 220′″: compressed gas injection hole
230, 230′, 230″, 230′″: compressed gas discharge guide
240″: installation member

1. A wafer storage container comprising:
a housing comprising an opening on a front side thereof and configured to accommodate a wafer therein; and
an air current controller provided on one side of the housing,
wherein the air current controller comprises:
a body provided in a hollow shape;
a compressed gas injection hole provided on one side of the body and configured to inject a compressed gas into the body; and
a compressed gas discharge guide configured to discharge the compressed gas inside the body to an outside of the body,
the body is provided in a shape extending a predetermined length in a vertical or horizontal direction of the housing, and
the housing comprises a plurality of spray slots configured to spray a purge gas to an inside of the housing.

2. The wafer storage container of claim 1, wherein the air current controller is detachably coupled to the housing.

3. The wafer storage container of claim 1, wherein the air current controller is detachably coupled to a wafer transfer automation module (equipment front end module (EFEM)) provided separately from the housing.

4. The wafer storage container of claim 1, wherein the air current controller is provided on each of left and right sides of the opening.

5. The wafer storage container of claim 4, wherein the air current controller is further provided on each of upper and lower sides of the opening, and the body of the air current controller provided on each of the upper, lower, left, and right sides of the opening has a communication space therein.

6. The wafer storage container of claim 5, wherein the space inside the body serves as a space in which the compressed gas flows.

7. The wafer storage container of claim 6, wherein the compressed gas discharge guide is provided in a shape having a portion that is curved toward the space.

8. The wafer storage container of claim 7, wherein the compressed gas inside the space is discharged along the compressed gas discharge guide, and the compressed gas is discharged to an outside of the housing through the opening together with the purge gas inside the housing.

9. The wafer storage container of claim 1, wherein the housing comprises:
a first housing having open front and rear sides; and
a second housing having an open front side, and the air current controller is provided between the first housing and the second housing.

10. The wafer storage container of claim 9, wherein the compressed gas discharge guide is provided at a position closer to the second housing than the first housing.

11. The wafer storage container of claim 10, wherein the air current controller is provided in a shape conforming to the first housing and the second housing, the body has a communication space therein, and the space inside the body serves as a space in which the compressed gas flows.

12. The wafer storage container of claim 11, wherein the compressed gas discharge guide is provided in a shape curved toward the space, the compressed gas inside the space is discharged along the compressed gas discharge guide, and the compressed gas is discharged to an outside of the housing through the opening together with the purge gas inside the housing.

13. A wafer storage container comprising:
a housing comprising an opening on a front side thereof and configured to receive a purge gas therein; and
an air current controller provided on one side of the housing and configured to supply a compressed gas into the housing,
wherein the airflow controller comprises:
a compressed gas discharge guide configured to discharge the compressed gas into the housing; and
a body provided in a hollow shape and having a side on which a compressed gas discharge guide is formed,
wherein when the compressed gas is discharged forward from rear of the housing along the compressed gas discharge guide, a pressure in front of the air current controller becomes higher than a pressure behind the air current controller and thereby an air current flowing forward from rear of the housing is generated.

14. The wafer storage container of claim 13, wherein the air current controller is detachably coupled to the one side of the housing at a position closer to front than to rear of the housing.

15. The wafer storage container of claim 13, wherein the air current controller is detachably coupled to the opening of the housing.

16. The wafer storage container of claim 1, wherein the air current controller is provided on the opening of the housing through an installation member at a predetermined interval from the housing.

17. The wafer storage container of claim 16, wherein the air current controller is directly coupled to the housing through the installation member or is installed on a ground or ceiling at an installation location.

18. The wafer storage container of claim 1, wherein a blocking partition is provided inside the housing, and the inside of the housing is divided into a plurality of areas by the blocking partition.

19. The wafer storage container of claim 18, wherein the air current controller is provided in each of the plurality of areas.

20. The wafer storage container of claim 18, further comprising a door,
wherein the door is configured to selectively open and close a front side of each of the plurality of areas.

21. A wafer storage container comprising:
a housing configured to accommodate a wafer therein; and
an air current controller provided on one side of the housing,
wherein a plurality of wafers are loaded at a predetermined interval in the housing,
a purge gas is charged into the housing, and
the air current controller comprises:
a body provided in a hollow shape; and
a compressed gas discharge guide formed in a shape curved toward an inside of the body in a rear-to-front direction of the housing,
wherein a compressed gas inside the body is discharged forward from rear of the housing along the compressed gas discharge guide, and
a flow of air inside the body is formed in a horizontal direction of the wafers.
